(19) United States
(12) Patent Application Publication
(10) Pub. No.: US 2026/0212929 A1
(43) Pub. Date: Jul. 23, 2026

(54) MEMORY DEVICE AND OPERATING METHOD THEREOF

(71) Applicant: SK hynix Inc., Gyeonggi-do (KR)

(72) Inventor: Seung Jun LEE, Gyeonggi-do (KR)

(21) Appl. No.: 19/399,671

(22) Filed: Nov. 25, 2025

(30) Foreign Application Priority Data
Jan. 22, 2025 (KR) 10-2025-0009364

(51) Int. Cl. G11C 16/08; G11C 5/14; G11C 16/30

(52) U.S. Cl. CPC G11C 16/08; G11C 5/147; G11C 16/30

(57) ABSTRACT

Provided is a memory device including a plurality of word lines coupled to a plurality of memory cells, a peripheral circuit configured to select a first word line from among the plurality of word lines and performing a forced drive operation of sequentially applying a first voltage, a forced drive voltage, and a settling voltage to the first word line, and a control logic circuit configured to control the peripheral circuit, wherein the forced drive voltage and the settling voltage applied to the first word line are provided from different regulators, respectively.

### CROSS-REFERENCE TO RELATED APPLICATION

The present application claims priority under 35 U.S.C. § 119(a) to Korean patent application number 10-2025-0009364 filed on January 22, 2025, the entire disclosure of which is incorporated by reference herein.

### BACKGROUND

### Technical Field

Various embodiments of the present disclosure relate generally to an electronic device, and more particularly, to a memory device and a method of operating the same.

### Related Art

A memory device may include a memory cell array which stores data and a peripheral circuit which performs a program operation, a read operation, and an erase operation. The peripheral circuit includes a voltage generator which generates a voltage for driving each component of the memory device.

The memory device is designed to perform a program operation, a read operation, or an erase operation according to a command which is output from a controller. The read operation may be performed by applying a read voltage provided by the voltage generator to a word line coupled to a selected memory cell.

The memory device generally applies an underdrive voltage to change an initial voltage of a word line and applies a settling voltage to cause the voltage of the word line to reach a target voltage level to stabilize a voltage level of the word line during a read operation. The peripheral circuit changes an initial voltage state of the word line with the underdrive voltage and then stabilizes the voltage of the word line to a target value by applying the settling voltage.

The voltage generator includes a regulator for generating an underdrive voltage and a settling voltage. When a stabilization operation of a selected word line is performed, one regulator generates both the settling voltage and the underdrive voltage.

Moreover, when the memory device uses a strong underdrive voltage to shorten a read operation time, an initial stabilization process of the voltage level of the word line may be accelerated, but it may take more time for the voltage level of the word line to reach a target voltage in a subsequent settling process. Therefore, simply increasing the underdrive voltage is difficult to effectively reduce the overall stabilization time.

### SUMMARY

Embodiments of the present disclosure provide a memory device capable of improving performance of the memory device and a method of operating the same.

According to an embodiment of the present disclosure, a memory device may include a plurality of word lines coupled to a plurality of memory cells, a peripheral circuit configured to select a first word line from among the plurality of word lines and perform a forced drive operation of sequentially applying a first voltage, a forced drive voltage, and a settling voltage to the first word line, and a control logic circuit configured to control the peripheral circuit, wherein the forced drive voltage and the settling voltage applied to the first word line are provided from different regulators, respectively.

According to an embodiment of the present disclosure, a memory device may include a plurality of word lines coupled to a plurality of memory cells, a peripheral circuit configured to select a first word line from among the plurality of word lines and perform a forced drive operation of sequentially applying a first voltage, a forced drive voltage, a first settling voltage, and a second settling voltage to the first word line, and a control logic circuit configured to control the peripheral circuit performing the forced drive operation, wherein the forced drive voltage and the first settling voltage applied to the first word line are provided from different regulators, and the first settling voltage the second settling voltage are provided from different regulators.

According to an embodiment of the present disclosure, a memory device may include a plurality of word lines coupled to a plurality of memory cells, a plurality of regulators configured to generate a first voltage, a forced drive voltage, and a settling voltage for forced drive operation, and a row decoder configured to sequentially apply the first voltage, the forced drive voltage, and the settling voltage generated by the plurality of regulators to a selected word line, wherein the forced drive voltage and the settling voltage applied to the first word line are provided from different regulators, respectively.

### BRIEF DESCRIPTION OF THE DRAWINGS

FIG. 1 is a diagram illustrating a memory device according to an embodiment of the present disclosure;

FIG. 2 is a diagram illustrating a memory block shown in FIG. 1;

FIG. 3 is a diagram illustrating the detailed configuration of a voltage generator, a row decoder, and the control logic circuit shown in FIG. 1;

FIG. 4 is a diagram illustrating a forced drive controller shown in FIG. 3;

FIG. 5 is a diagram illustrating a voltage range of a regulator;

FIG. 6 is a diagram illustrating an underdrive operation during a read operation of a memory device according to a first embodiment of the present disclosure;

FIG. 7 is a diagram illustrating an underdrive operation during a read operation of a memory device according to a second embodiment of the present disclosure;

FIG. 8 is a diagram illustrating an overdrive operation during a read operation of a memory device according to a third embodiment of the present disclosure;

FIG. 9 is a diagram illustrating an overdrive operation during a read operation of a memory device according to a fourth embodiment of the present disclosure;

FIG. 10 is a diagram illustrating a memory card system to which a memory device according to an embodiment of the present disclosure is applied; and

FIG. 11 is a diagram illustrating a Solid State Drive (SSD) system to which a memory device according to an embodiment of the present disclosure is applied.

### DETAILED DESCRIPTION

Specific structural or functional descriptions of embodiments in accordance with concepts which are disclosed in this specification are illustrated only to describe the embodiments in accordance with the concepts. The embodiments in accordance with the concepts may be carried out by various forms but the descriptions are not limited to the embodiments described in this specification.

While terms such as "first" and "second" may be used to describe various components, such components must not be understood as being limited to the above terms. The above terms are used only to distinguish one component from another.

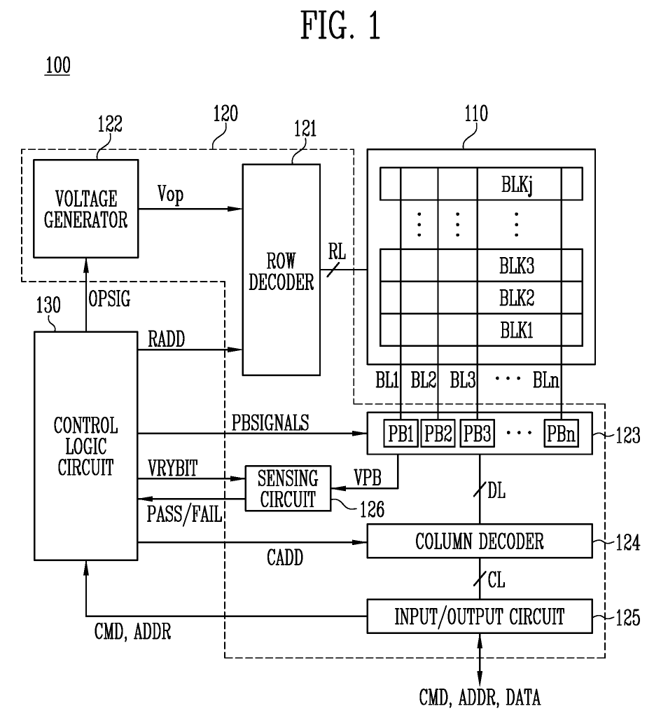

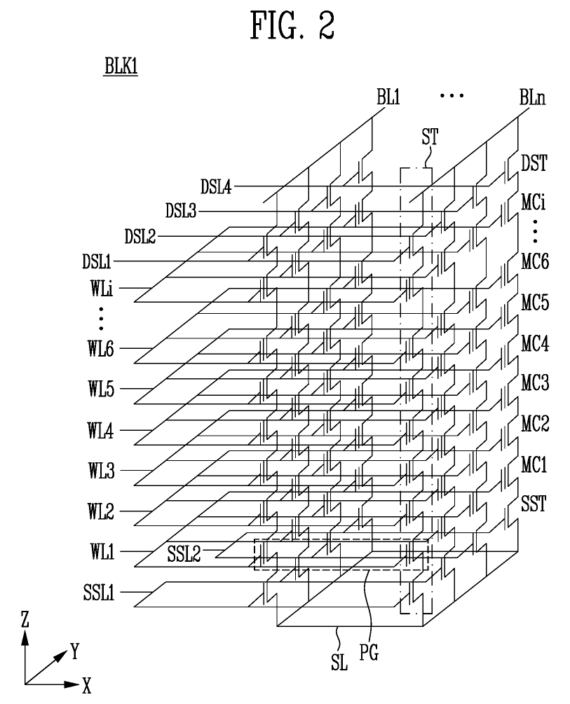

FIG. 1 is a diagram illustrating a memory device 100 according to an embodiment of the present disclosure, and FIG. 2 is a diagram illustrating a memory block shown in FIG. 1.

Referring to FIGS. 1 and 2, the memory device 100 may include a memory cell array 110, a peripheral circuit 120, and a control logic circuit 130.

The memory cell array 110 includes first to j-th memory blocks BLK1 to BLKj. The first to j-th memory blocks BLK1 to BLKj are coupled to a row decoder 121 through row lines RL. The first to j-th memory blocks BLK1 to BLKj may be coupled to a page buffer group 123 through first to n-th bit lines BL1 to BLn. Each of the first to j-th memory blocks BLK1 to BLKj includes a plurality of cell strings ST, and each of the plurality of cell strings ST includes a plurality of memory cells. In an embodiment, the plurality of memory cells are non-volatile memory cells. Memory cells coupled to the same word line may be defined as a single page PG. Thus, one memory block may include multiple pages.

The first to j-th memory blocks BLK1 to BLKj may be configured to be identical to each other. Thus, a structure of a memory block, for example, a structure of the first memory block BLK1 is described in detail below.

Referring to FIG. 2, the first memory block BLK1 includes the cell strings ST coupled between the first to n-th bit lines BL1 to BLn and a source line SL. Since the first to n-th bit lines BL1 to BLn extend in a Y direction and are arranged spaced apart from each other in an X direction, the cell strings ST may also be arranged spaced apart in the X and Y directions. For example, the cell strings ST may be coupled between the first bit line BL1 and the source line SL, and the cell strings ST may be arranged between the second bit line BL2 and the source line SL. In this manner, the cell strings ST may be arranged between the n-th bit line BLn and the source line SL. The cell strings ST may extend in a Z direction.

One of the cell strings ST coupled to the n-th bit line BLn is described as an example. The cell string ST may include a source select transistor SST, first to i-th memory cells MC1 to MCi, and a drain select transistor DST. Since FIG. 2 schematically shows the first memory block BLK1 to describe the structure of the memory block, the number of source select transistors SST, the number of first to i-th memory cells MC1 to MCi, and the number of drain select transistors DST included in the cell strings ST may be changed according to the memory device.

Gates of the source select transistors SST included in different cell strings may be coupled to a first or second source select line SSL1 or SSL2, gates of the first to i-th memory cells MC1 to MCi may be coupled to first to i-th word lines WL1 to WLi, and gates of the drain select transistors DST may be coupled to one of first to fourth drain select lines DSL1 to DSL4.

The lines coupled to the first memory block BLK1 are described below in more detail. The source select transistors SST arranged in the X direction may be coupled to the same source select line, and the source select transistors SST arranged in the Y direction may be coupled to separate source select lines. For example, some of the source select transistors SST arranged in the Y direction may be coupled to the first source select line SSL1, and the others may be coupled to the second source select line SSL2. The second source select line SSL2 is separate from the first source select line SSL1. Thus, the voltage applied to the first source select line SSL1 may be the same as or different from the voltage applied to the second source select line SSL2.

Memory cells formed in the same layer among the first to i-th memory cells MC1 to MCi may be coupled to the same word line. For example, the first memory cells MC1 included in different cell strings ST may be commonly coupled to the first word line WL1, and the i-th memory cells MCi included in different cell strings ST may be commonly coupled to the i-th word line WLi. A group of memory cells included in different cell strings ST and coupled to the same word line form the page PG. Program and read operations may be performed on a per-page (PG) basis, and pre-program and erase operations may be performed in a per-memory block basis. Operations performed in units of memory blocks may be performed on all pages included in a selected memory block.

The drain select transistors DST arranged in the Y direction may be coupled to the first to fourth drain select lines DSL1 to DSL4 separated from each other. More specifically, the drain select transistors DST arranged in the X direction may be coupled to the same drain select line, and the drain select transistors DST arranged in the Y direction may be coupled to the first to fourth drain select lines DSL1 to DSL4 separated from each other. Since the first to fourth drain select lines DSL1 to DSL4 are separated from each other, different voltages may be applied to the first to fourth drain select lines DSL1 to DSL4.

Referring to FIGS. 1 and 2, the row lines RL may include the source select lines SSL1 and SSL2, the plurality of word lines WL1 to WLi, and the drain select lines DSL1 to DSL4. The source select lines SSL1 and SSL2, the plurality of word lines WL1 to WLi, and the drain select lines DSL1 to DSL4 may be coupled to each of the first to j-th memory blocks BLK1 to BLKj. Each of the bit lines BL1 to BLn may be coupled to at least one cell string.

Memory cells included in the memory cell array 110 may be programmed in a Multi-Level Cell (MLC) scheme, a Triple Level Cell (TLC) scheme, or a Quad Level Cell (QLC) scheme depending on the number of bits of data stored. Each of the memory cells programmed in the MLC scheme may store two bits of data. Each of the memory cells programmed in the TLC scheme may store three bits of data. Each of the memory cells programmed in the QLC scheme may store four bits of data. How memory cells are programmed may vary depending on the memory device. In addition to the schemes as described above, a scheme of programming five or more bits of data in one memory cell may be used.

The control logic circuit 130 may control the peripheral circuit 120 to perform a program operation, a read operation, or an erase operation on a selected region of the memory cell array 110. For example, the peripheral circuit 120 may apply various operating voltages to the row lines RL and the first to n-th bit lines BL1 to BLn, or may selectively discharge the row lines RL and the first to N-th bit lines BL1 to BLn in response to control of the control logic circuit 130.

The peripheral circuit 120 may include the row decoder 121, a voltage generator 122, the page buffer group 123, a column decoder 124, an input/output circuit 125, and a sensing circuit 126.

The row decoder 121 is coupled to the memory cell array 110 through the row lines RL. The row lines RL may include at least one source select line, a plurality of word lines, and at least one drain select line. In an embodiment, the word lines may include normal word lines and dummy word lines.

The row decoder 121 decodes a row address RADD received from the control logic circuit 130. The row decoder 121 selects at least one of the memory blocks BLK1 to BLKj according to the decoded address. In addition, the row decoder 121 may transmit operating voltages Vop generated by the voltage generator 122 to the row lines RL of the selected memory block according to the decoded address.

For example, during a program operation, the row decoder 121 may apply a program voltage to a selected word line and a program pass voltage at a level lower than that of the program voltage to an unselected word line. During a program verify operation, the row decoder 121 may apply a verify voltage to the selected word line and a verify pass voltage greater than the verify voltage to the unselected word line. During a read operation, the row decoder 121 may apply a read voltage to the selected word line and a read pass voltage greater than the read voltage to the unselected word line.

An erase operation of the memory device 100 is performed in units of memory blocks. During the erase operation, the row decoder 121 may select one memory block according to the decoded address. During the erase operation, the row decoder 121 may apply a 0 V or a ground voltage to the word lines coupled to the selected memory block, or may cause the word lines to float.

The voltage generator 122 operates in response to control of the control logic circuit 130. The voltage generator 122 generates a plurality of voltages by using an external power supply voltage supplied to the memory device 100. Specifically, the voltage generator 122 may generate various operating voltages Vop for program, read, and erase operations in response to an operation signal OPSIG generated by the control logic circuit 130. For example, the voltage generator 122 may generate a program voltage, a verify voltage, a pass voltage, a read voltage, an erase voltage, and the like in response to the control of the control logic circuit 130.

The page buffer group 123 includes first to n-th page buffers PB1 to PBn. The first to n-th page buffers PB1 to PBn are coupled to the memory cell array 110 through the first to n-th bit lines BL1 to BLn. The first to n-th page buffers PB1 to PBn operate in response to control of the control logic circuit 130. More specifically, the first to n-th page buffers PB1 to PBn may operate in response to page buffer control signals PBSIGNALS. For example, the first to n-th page buffers PB1 to PBn may temporarily store data received through the first to n-th bit lines BL1 to BLn, or may sense voltages or currents of the first to n-th bit lines BL1 to BLn during a read or verify operation.

More specifically, during a program operation, when a program voltage is applied to the selected word line, the first to n-th page buffers PB1 to PBn may transmit data DATA received through the input/output circuit 125 to selected memory cells through the first to n-th bit lines BL1 to BLn. The memory cells of the selected page are programmed according to the transferred data DATA. During a program verify operation, the first to n-th page buffers PB1 to PBn read page data by sensing the voltages or currents received from the selected memory cells through the first to n-th bit lines BL1 to BLn.

During a read operation, the first to n-th page buffers PB1 to PBn read the data DATA from the memory cells of the selected page through the first to n-th bit lines BL1 to BLn, and output the read data DATA to the input/output circuit 125 under the control of the column decoder 124.

During an erase operation, the first to n-th page buffers PB1 to PBn may float the first to n-th bit lines BL1 to BLn, or may apply an erase voltage to the first to n-th bit lines BL1 to BLn.

The column decoder 124 may transfer data between the input/output circuit 125 and the page buffer group 123 in response to a column address CADD. For example, the column decoder 124 may exchange data with the first to n-th page buffers PB1 to PBn through data lines DL, or may exchange data with the input/output circuit 125 through column lines CL.

The input/output circuit 125 may transmit a command CMD and an address ADDR received from the memory controller to the control logic circuit 130, or may exchange the data DATA with the column decoder 124.

The sensing circuit 126 may generate a reference current in response to an allowable bit signal VRYBIT during a read operation or a verify operation, and may compare a sensing voltage VPB received from the page buffer group 123 with a reference voltage generated by the reference current to output a pass signal PASS or a fail signal FAIL.

The control logic circuit 130 may output the operation signal OPSIG, the row address RADD, the page buffer control signals PBSIGNALS, and the allowable bit signal VRYBIT in response to the command CMD and the address ADDR to control the peripheral circuit 120. For example, the control logic circuit 130 may control a read operation of a selected memory block in response to a sub-block read command and an address. Further, the control logic circuit 130 may control an erase operation of the selected sub-block included in the selected memory block in response to a sub-block erase command and an address. In addition, control logic circuit 130 may determine whether a verify operation passes or fails in response to the pass or fail signal PASS or FAIL.

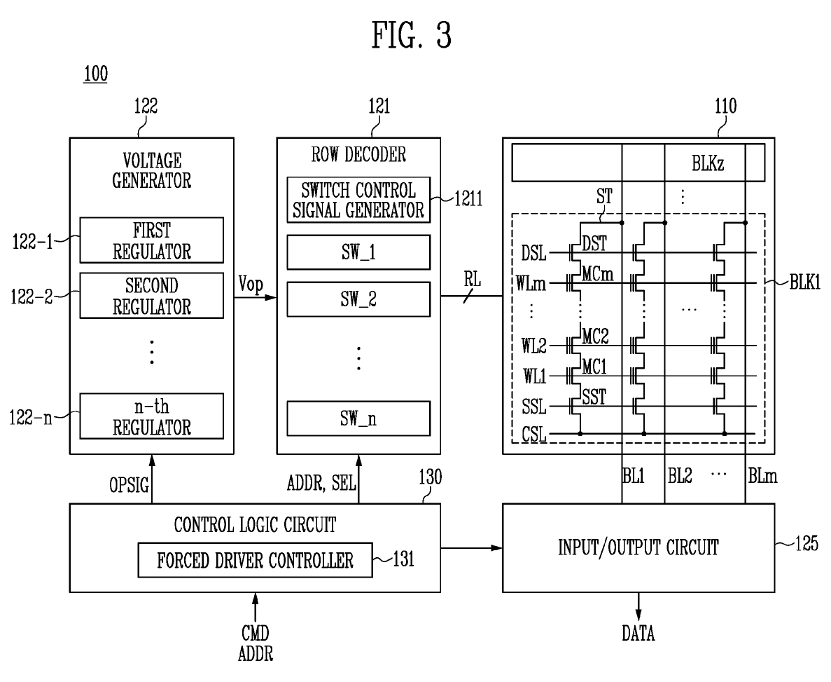

FIG. 3 is a diagram illustrating detailed configurations of the voltage generator 122, the row decoder 121, and the control logic circuit 130 as shown in FIG. 1.

Referring to FIG. 3, the voltage generator 122 may include a plurality of regulators 122-1 to 122-n. The plurality of regulators 122-1 to 122-n may generate and apply the operating voltages Vop to the plurality of word lines WL1 to WLm. The plurality of regulators may generate different ranges of voltages.

The row decoder 121 includes a switch control signal generator 1211 and a plurality of switching circuits SW_1 to SW_n. The plurality of switching circuits SW_1 to SW_n may be coupled to the plurality of regulators 122-1 to 122-n of the voltage generator 122.

The switch control signal generator 1211 may generate a switch control signal for controlling the plurality of switching circuits SW_1 to SW_n in response to a selection signal SEL of the control logic circuit 130. The selection signal SEL may include a signal for selecting a switching circuit to be turned on and a switching circuit to be turned off from among the plurality of switching circuits SW_1 to SW_n.

The plurality of switching circuits SW_1 to SW_n may be coupled to one of the plurality of word lines WL1 to WLm. In addition, the plurality of switching circuits SW_1 to SW_n may be coupled to the plurality of regulators 122-1 to 122-n. The plurality of switching circuits SW_1 to SW_n may couple the plurality of word lines WL1 to WLm to the plurality of regulators 122-1 to 122-n.

For example, the first switching circuit SW_1 may couple a first word line WL_1 and the plurality of regulators 122-1 to 122-n. The first word line WL_1 may receive operating voltages from the plurality of regulators 122-1 to 122-n through the first switching circuit SW_1.

For example, a second switching circuit SW_2 may couple a second word line WL_2 with the plurality of regulators 122-1 to 122-n. The second word line WL_2 may receive operating voltages from the plurality of regulators 122-1 to 122-n through the second switching circuit SW_2.

The control logic circuit 130 may control the voltage generator 122, the row decoder 121, and the input/output circuit 125. The control logic circuit 130 may generate various signals in response to the command CMD and the address ADDR transferred from an external device to control the peripheral circuit 120.

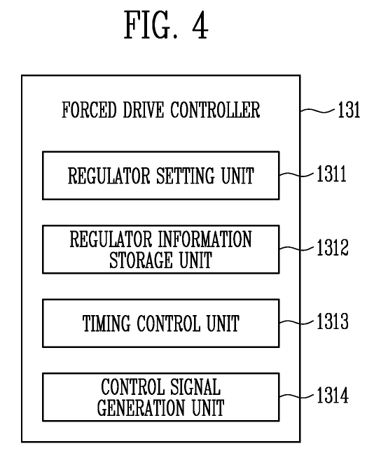

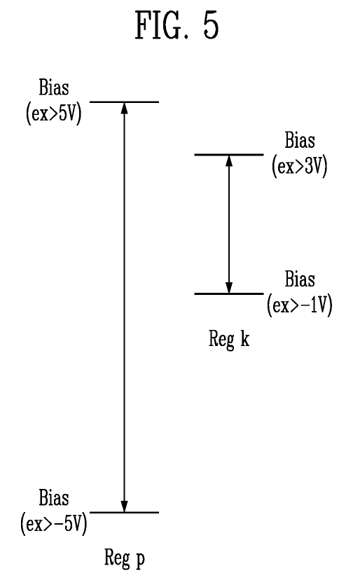

FIG. 4 is a diagram illustrating the forced drive controller 131 shown in FIG. 3, and FIG. 5 is a diagram illustrating a voltage range of a regulator.

Referring to FIGS. 4 and 5, the forced drive controller 131 includes a regulator setting unit 1311, a regulator information storage unit 1312, a timing control unit 1313, and a control signal generation unit 1314. The regulator setting unit 1311, regulator information storage unit 1312, timing control unit 1313, and control signal generation unit 1314 include all circuits, systems, software, firmware and devices necessary for their respective operations and functions.

The regulator setting unit 1311 may select a temporary drive regulator IReg based on forced drive voltage range information, settling voltage range information, and command information.

A normal drive regulator NReg generates a drive voltage, and the temporary drive regulator IReg generates a forced drive voltage, e.g., one of an overdrive voltage and an underdrive voltage. Each of the normal drive regulator NReg and temporary drive regulator IReg may also generate the other type of voltage. In FIG. 4 and FIG. 5, the normal drive regulator NReg is already set, hence a method of setting the temporary drive regulator IReg will be described.

More specifically, the regulator setting unit 1311 may select a temporary drive regulator having a voltage range corresponding to the forced drive voltage or the settling voltage information, based on the forced drive voltage range information, the settling voltage range information, and voltage generation range information of each of the plurality of regulators which are stored in the regulator information storage unit 1312.

In addition, the regulator setting unit 1311 may select a regulator unrelated to command execution as a temporary drive regulator from among regulators having the voltage range corresponding to the forced drive voltage, based on the forced drive voltage information and the voltage range information of each of the regulators as stored in the regulator information storage unit 1312.

The forced drive voltage information may refer to information about an overdrive voltage or an underdrive voltage. The settling voltage information may refer to information on a settling voltage. The voltage range information of each regulator may refer to a voltage range which may be generated as set for each regulator.

For example, when performing forced driving during a read operation, the regulator setting unit 1311 may select a regulator related to an erase operation unrelated to the read operation and having a voltage range corresponding to the forced drive voltage or the settling voltage information as a temporary drive regulator.

When the regulator setting unit 1311 finds both a regulator corresponding to the forced drive voltage range information and a regulator corresponding to the settling voltage range information from the regulators not involved in the execution of the corresponding command, the regulator setting unit 1311 may preferentially select the regulator corresponding to the force drive voltage range information as the temporary drive regulator.

As shown in FIG. 5, the regulator information storage unit 1312 stores regulator voltage generation range information for a voltage generation range which may be generated by each of the plurality of regulators. For example, a p-th regulator Reg p may have a bias voltage generation range between −5 V and 5 V, and a k-th regulator Reg k may have a bias voltage generation range between −1 V and 3 V. The regulator information storage unit 1312 may provide the information on the regulator voltage generation range of each of a plurality of regulators to the regulator setting unit 1311.

The timing control unit 1313 controls switching timings of the temporary drive regulator IReg and the normal drive regulator NReg. The timing control unit 1313 provides switching timing information of the temporary drive regulator IReg and the normal drive regulator NReg based on predetermined switching timing information according to a difference between a settling voltage and a forced drive voltage. Furthermore, the timing control unit 1313 may correct the switching timing information based on the selected temporary drive regulator IReg information generated by the regulator setting unit 1311.

The control signal generation unit 1314 provides a control signal to the switching control signal generator 1211 (FIG. 3) based on the switch timing between the temporary drive regulator IReg and the normal drive regulator NReg. The switching control signal generator 1211 (FIG. 3) may control the plurality of switching circuits SW_1 to SW_n based on the control signal provided from the control signal generation unit 1314.

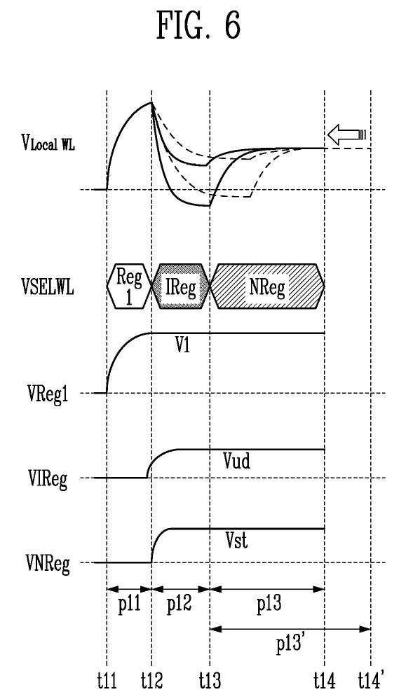

FIGS. 6 to 9 are diagrams illustrating a forced drive operation during a read operation of a memory device according to first to fourth embodiments of the present disclosure.

The dotted lines in a word line voltage (VLocalWL) graph refer to a case where a forced drive voltage and a settling voltage are generated by one regulator, and the solid lines in the graph refer to a case where the forced drive voltage and the settling voltage are generated by separate regulators.

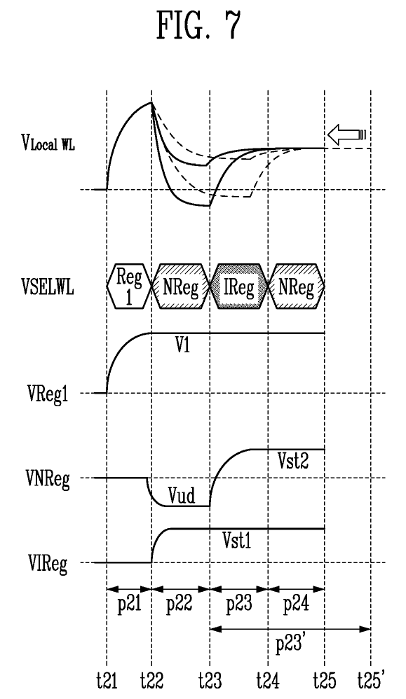

In FIGS. 6 and 7, in the word line voltage (VLocalWL) graph, a dotted or solid line located relatively above within the same time period may mean a voltage of a word line located far from a voltage source, and a dotted or solid line located relatively below may mean a voltage of a word line located close to the voltage source.

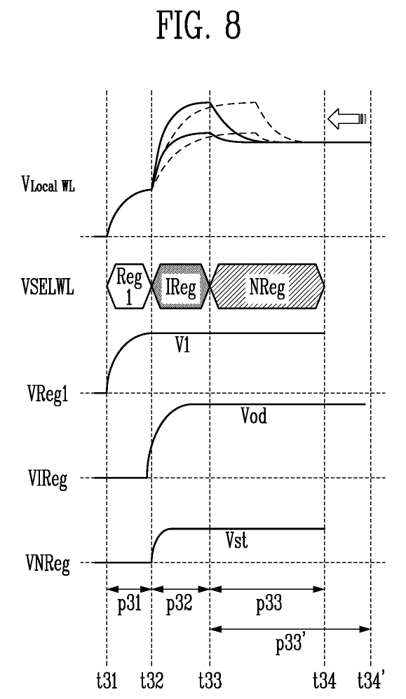

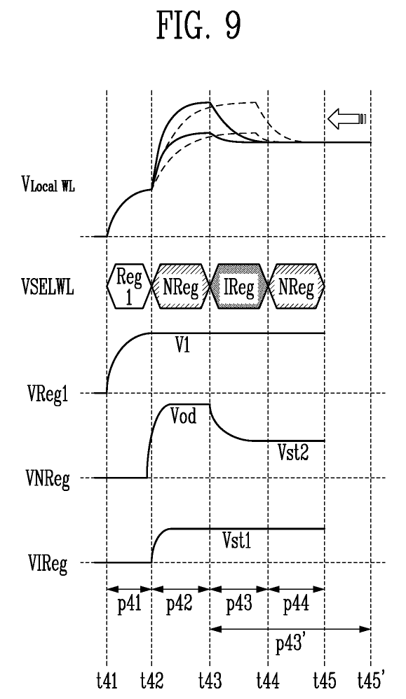

In FIGS. 8 and 9, in the word line voltage (VLocalWL) graph, a relatively lower dotted line or solid line within the same time period may mean a voltage of a word line located far from the voltage source, and a relatively greater dotted line and solid line may mean a voltage of a word line located close to the voltage source.

In the graph, VSELWL means a regulator selecting signal for providing a voltage to a selected word line, and VReg1, VIReg, and VNReg mean voltages provided by a first regulator Reg1, the temporary drive regulator IReg, and the normal drive regulator NReg, respectively.

The forced drive voltage may be one of an underdrive voltage Vud and an overdrive voltage Vod. In addition, the normal drive regulator NReg generates one of a settling voltage Vst and a forced drive voltage (Vud or Vod). The temporary drive regulator IReg generates the other voltage other than the voltage generated by the normal drive regulator NReg.

FIG. 6 is a diagram illustrating an underdrive operation during a read operation of a memory device according to a first embodiment of the present disclosure. Referring to FIG. 6, the first regulator Reg1 provides a first voltage V1, the temporary drive regulator IReg provides the underdrive voltage Vud, and the normal drive regulator NReg provides the settling voltage Vst.

The control logic circuit 130 (FIG. 3) may control the row decoder 121 (FIG. 3) to switch the voltage source providing the voltage to the selected word line from the first regulator Reg1 to the temporary drive regulator IReg, or from the temporary drive regulator IReg to the normal drive regulator NReg. That is, the row decoder 121 may immediately change the voltage applied to the selected word line by switching the voltage source providing the voltage to the selected word line from the first regulator Reg1 to the temporary drive regulator IReg, and from the temporary drive regulator IReg to the normal drive regulator NReg.

Referring to FIG. 6, during a (1-1)-th period p11 from a (1-1)-th time point t11 to a (1-2)-th time point t12, the peripheral circuit 120 (FIG. 1) may apply the first voltage V1 to the selected word line. The first voltage V1 may be provided from the first regulator Reg1. For example, when an underdrive operation is performed during a read operation on the selected word line, the first voltage V1 may be a pass voltage.

During a (1-2)-th period p12 from the (1-2)-th time point t12 to a (1-3)-th time point t13, the peripheral circuit 120 (FIG. 1) may apply the underdrive voltage Vud to the selected word line. The underdrive voltage Vud may then be provided from the temporary drive regulator IReg.

For example, when an underdrive operation is performed during a read operation on a selected word line, after a pass voltage is applied during the (1-1)-th period p11, the row decoder 121 (FIG. 3) may switch a regulator which provides a voltage to the selected word line from the first regulator Reg1 to the temporary drive regulator IReg. Immediately upon switching from the first regulator Reg1 to the temporary drive regulator IReg, the underdrive voltage Vud generated by the temporary drive regulator IReg is provided to the selected word line.

During a (1-3)-th period p13 from the (1-3)-th time point t13 to a (1-4)-th time point t14, the peripheral circuit 120 (FIG. 1) may apply the settling voltage Vst to the selected word line. The settling voltage Vst may then be provided from the normal drive regulator NReg.

For example, when an underdrive operation is performed during a read operation on a selected word line, after the underdrive voltage Vud generated by the temporary drive regulator IReg is provided to the selected word line, the regulator which provides the voltage to the selected word line at the (1-3)-th time point t13 switches from the temporary drive regulator IReg to the normal drive regulator NReg. The settling voltage Vst generated by the normal drive regulator NReg is provided to the selected word line from the (1-3)-th time point t13.

The normal drive regulator NReg may generate the settling voltage Vst from a time point earlier than the (1-3)-th time point t13. For example, the normal drive regulator NReg may generate the settling voltage Vst from the (1-2)-th time point t12 prior to providing the voltage to the selected word line. The normal drive regulator NReg may immediately provide the settling voltage Vst to the selected word line from the (1-3)-th time point t13 corresponding to the switching time point by generating the settling voltage Vst in advance earlier than the (1-3)-th time point t13 which is the switching time point.

A conventional memory device performs an underdrive operation on a selected word line by applying an underdrive voltage and a settling voltage provided by one regulator to a selected word line. In the conventional memory device, when a strong underdrive voltage is applied to the word line to shorten an underdrive operation time, the time for the regulator generating the strong underdrive voltage to generate the settling voltage may be increased. That is, a settling period p13′ may end at a (1-4’)-th time point t14′. Therefore, in the conventional memory device, it was not easy to shorten the underdrive operation time of the memory device.

In the memory device according to the first embodiment of the present disclosure, an underdrive voltage and a settling voltage for an underdrive operation on a selected word line are generated from different regulators and provided to the selected word line. Therefore, an underdrive operation time of the memory device may be reduced since the underdrive voltage and the settling voltage are applied to the selected word line from the different regulators.

FIG. 7 is a diagram illustrating an underdrive operation during a read operation of a memory device according to a second embodiment of the present disclosure. In FIG. 7, the first regulator Reg1 provides the first voltage V1, the normal drive regulator NReg provides the underdrive voltage Vud and a second settling voltage Vst2, and the temporary drive regulator IReg provides a first settling voltage Vst1.

The control logic circuit 130 (FIG. 3) may control the row decoder 121 (FIG. 3) to switch from the first regulator Reg1 to the normal drive regulator NReg, from the normal drive regulator NReg to the temporary drive regulator IReg, or from the temporary drive regulator IReg to the normal drive regulator NReg. The row decoder 121 in FIG. 3 may immediately change the voltage applied to the selected word line by switching the first regulator Reg1, the normal drive regulator NReg, and the temporary drive regulator IReg.

Referring to FIG. 7, during a (2-1)-th period p21 from a (2-1)-th time point t21 to a (2-2)-th time point t22, the peripheral circuit 120 (FIG. 1) may apply the first voltage V1 to the selected word line. The first voltage V1 may be provided from the first regulator Reg1. For example, when an underdrive operation is performed during a read operation on the selected word line, the first voltage V1 may be a pass voltage.

During a (2-2)-th period p22 from the (2-2)-th time point t22 to a (2-3)-th time point t23, the peripheral circuit 120 (FIG. 1) may apply the underdrive voltage Vud to the selected word line. The underdrive voltage Vud may then be provided from the normal drive regulator NReg.

For example, when an underdrive operation is performed during a read operation on a selected word line, after a pass voltage is applied during the (2-1)-th period p21, the row decoder 121 (FIG. 3) may switch the regulator which provides the voltage to the selected word line from the first regulator Reg1 to the normal drive regulator NReg. As the first regulator Reg1 is switched to the normal drive regulator NReg, the underdrive voltage Vud generated by the normal drive regulator NReg is immediately provided to the selected word line.

During a (2-3)-th period p23 from the (2-3)-th time point t23 to a (2-4)-th time point t24, the peripheral circuit 120 (FIG. 1) may apply the first settling voltage Vst1 to the selected word line. The first settling voltage Vst1 is provided by the temporary drive regulator IReg. The temporary drive regulator IReg may generate the first settling voltage Vst1 from a time point earlier than the (2-3)-th time point t23. The temporary drive regulator IReg may immediately provide the first settling voltage Vst1 to the selected word line from the (2-3)-th time point t23 corresponding to the switching time point by generating the first settling voltage Vst1 in advance earlier than the (2-3)-th time point t23.

During a (2-4)-th period p24 from the (2-4)-th time point t24 to a (2-5)-th time point t25, the peripheral circuit 120 (FIG. 1) may apply the second settling voltage Vst2 to the selected word line. The normal drive regulator NReg may provide the second settling voltage Vst2. The normal drive regulator NReg may generate the second settling voltage Vst2 before the (2-4)-th time point t24.

The second settling voltage Vst2 may be the same voltage as the first settling voltage Vst1. The temporary drive regulator IReg which provides the first settling voltage Vst1 provides the voltage temporarily. The normal drive regulator NReg may perform the operation performed by the temporary drive regulator IReg instead.

When the normal drive regulator NReg which generates and provides the underdrive voltage Vud to the selected word line during the (2-2)-th period p22 provides the first settling voltage Vst1 to the selected word line in the immediately following (2-3)-th period p23, it takes time to convert from the underdrive voltage Vud to the first settling voltage Vst1. Referring to the dotted line in FIG. 7, it is expressed that converting the voltage (VNReg) generated by the normal drive regulator NReg from the underdrive voltage Vud to the second settling voltage Vst2 is delayed compared to that indicated by the solid line, occurring later than the (2-3)-th time point t23. The dotted lines in a word line voltage (VLocalWL) graph refer to a case where a forced drive voltage and a settling voltage are generated by one regulator, and the solid lines in the graph refer to a case where the forced drive voltage and the settling voltage are generated by separate regulators. Accordingly, in the peripheral circuit 120 in FIG. 1 of the present embodiment, the temporary drive regulator IReg stably provides the first settling voltage Vst1 to the selected word line during the (2-3)-th period p23 until the normal drive regulator NReg provides the second settling voltage Vst2 to the selected word line. Finally, the normal drive regulator NReg may stably provide the second settling voltage Vst2 to the selected word line.

That is, when the underdrive driving operation is performed during the read operation on the selected word line, after the underdrive voltage Vud generated by the normal drive regulator NReg is provided to the selected word line, the regulator which provides the voltage to the selected word line at the (2-3)-th time point t23 switches from the normal drive regulator (NReg) to the temporary drive regulator IReg. Thus, the first settling voltage generated by the temporary drive regulator IReg is provided to the selected word line from the (2-3)-th time point t23. The regulator which provides the voltage to the selected word line switches from the temporary drive regulator IReg to the normal drive regulator NReg at the (2-4)-th time point t24. Thus, the second settling voltage Vst2 generated by the normal drive regulator NReg is provided to the selected word line from the (2-4)-th time point t24.

In a conventional memory device, an underdrive voltage and a settling voltage are generated from one regulator and provided to a selected word line, so that an underdrive operation is performed on the selected word line. In the conventional memory device, when a strong underdrive voltage is applied to the word line to shorten an underdrive operation time, the time for the regulator generating the strong underdrive voltage to switch from an underdrive voltage to a settling voltage is increased. A settling period p23′ may end at a (2-5)-th time point t25. Therefore, in the conventional memory device, it was not easy to shorten the underdrive operation time of the memory device.

When the memory device according to the second embodiment of the present disclosure performs an underdrive operation on a selected word line, an underdrive voltage and a settling voltage are generated from different regulators and provided to the selected word line. Therefore, an underdrive operation time of the memory device may be easily reduced by providing the underdrive voltage and the settling voltage to the selected word line from the regulators which generate different voltages instead of one regulator.

FIG. 8 is a diagram illustrating an overdrive operation during a read operation of a memory device according to a third embodiment of the present disclosure. To perform the overdrive operation during the read operation on the selected word line as shown in FIG. 8, the first regulator Reg1 provides a first voltage, the temporary drive regulator IReg provides an overdrive voltage, and the normal drive regulator NReg provides a settling voltage.

The row decoder 121 (FIG. 3) may switch from the first regulator Reg1 to the temporary drive regulator IReg, from the temporary drive regulator IReg to the normal drive regulator NReg, or from the normal drive regulator NReg to the temporary drive regulator IReg under the control of the control logic circuit 130 (FIG. 3). The row decoder 121 in FIG. 3 may immediately change the voltage applied to the selected word line by switching the first regulator Reg1, the normal drive regulator NReg, and the temporary drive regulator IReg supplying the voltage to the selected word line.

Referring to FIG. 8, during a (3-1)-th period p31 from a (3-1)-th time point t31 to a (3-2)-th time point t32, the peripheral circuit 120 (FIG. 1) may apply the first voltage V1 to the selected word line. The first voltage V1 may be provided from the first regulator Reg1. For example, when an overdrive operation is performed during a read operation on the selected word line, the first voltage V1 may be a pass voltage.

During a (3-2)-th period p32 from the (3-2)-th time point t32 to a (3-3)-th time point t33, the peripheral circuit 120 (FIG. 1) may apply the overdrive voltage Vod to the selected word line. The overdrive voltage Vod may then be provided from the temporary drive regulator IReg.

For example, when an overdrive operation is performed during the read operation on the selected word line, after the pass voltage is applied to the selected word line during the (3-1)-th period p31, the row decoder 121 (FIG. 3) may switch the regulator which provides the voltage to the selected word line from the first regulator Reg1 to the temporary drive regulator IReg. Immediately upon switching from the first regulator Reg1 to the temporary drive regulator IReg, the overdrive voltage generated by the temporary drive regulator IReg is provided to the selected word line.

During a (3-3)-th period p33 from a (3-3)-th time point t33 to a (3-4)-th time point t34, the peripheral circuit 120 (FIG. 1) may apply the settling voltage Vst to the selected word line. The settling voltage Vst may then be provided from the normal drive regulator NReg.

For example, when an overdrive operation is performed during the read operation on the selected word line, after the overdrive voltage Vod generated by the temporary drive regulator IReg is provided to the selected word line, the regulator which provides the voltage to the selected word line switches from the temporary drive regulator IReg to the normal drive regulator NReg at the (3-3)-th time point t33. The settling voltage Vst generated by the normal drive regulator NReg is provided to the selected word line from the (3-3)-th time point t33.

The normal drive regulator NReg may generate the settling voltage Vst from a time point earlier than the (3-3)-th time point t33. For example, the normal drive regulator NReg may generate the settling voltage Vst from the (3-2)-th time point t32 prior to providing the voltage to the selected word line. The normal drive regulator NReg may immediately provide the settling voltage Vst to the selected word line from the (3-3)-th time point t33 corresponding to the switching point by generating the settling voltage Vst in advance at a time point earlier than the (3-3)-th time point t33.

A conventional memory device performs an overdrive operation on a selected word line by applying an overdrive voltage and a settling voltage provided by one regulator to the selected word line. In the conventional memory device, when a strong overdrive voltage is applied to the word line to shorten an overdrive operation time, the time for the regulator generating the strong overdrive voltage to generate and provide the settling voltage is increased, so that a settling period p33′ may end at a (3-4′)-th time point t34′. Therefore, in the conventional memory device, it was not easy to shorten the overdrive operation time of the memory device.

When the memory device according to the third embodiment of the present disclosure performs an overdrive operation on a selected word line, an overdrive voltage and a settling voltage are generated from different regulators and provided to the selected word line. Therefore, the selected word line is provided with the overdrive voltage and the settling voltage from the regulators which generate different voltages instead of one regulator, so that an overdrive operation time of the memory device may be easily reduced.

FIG. 9 is a diagram illustrating an overdrive operation during a read operation of a memory device according to a fourth embodiment of the present disclosure. To perform the overdrive operation on the selected word line in FIG. 9, the first regulator Reg1 provides the first voltage V1, the normal drive regulator NReg provides the overdrive voltage Vod and the second settling voltage Vst2, and the temporary drive regulator IReg provides the first settling voltage Vst1.

The control logic circuit 130 in FIG. 3 may control the row decoder 121 in FIG. 3 to switch from the first regulator Reg1 to the normal drive regulator NReg, from the normal drive regulator NReg to the temporary drive regulator IReg, or from the temporary drive regulator IReg to the normal drive regulator NReg. The row decoder 121 may immediately change the voltage applied to the selected word line by switching the first regulator Reg1, the normal drive regulator NReg, and the temporary drive regulator IReg.

Referring to FIG. 9, during a (4-1)-th period p41 from a (4-1)-th time point t41 to a (4-2)-th time point t42, the peripheral circuit 120 (FIG. 1) may apply the first voltage V1 to the selected word line. The first voltage V1 may be provided from the first regulator Reg1. For example, when an overdrive operation is performed during a read operation on the selected word line, the first voltage V1 may be a pass voltage.

During a (4-2)-th period p42 from the (4-2)-th time point t42 to a (4-3)-th time point t43, the peripheral circuit 120 (FIG. 1) may apply the overdrive voltage Vod to the selected word line. The overdrive voltage Vod may then be provided from the normal drive regulator NReg.

For example, when an overdrive operation is performed during a read operation on a selected word line, after a pass voltage is applied during the (4-1)-th period p41, the row decoder 121 (FIG. 3) may switch from the first regulator Reg1 which provides the voltage to the selected word line to the normal drive regulator NReg. As the first regulator Reg1 is switched to the normal drive regulator NReg, the overdrive voltage Vod generated by the normal drive regulator NReg is immediately provided to the selected word line.

During a (4-3)-th period p43 from a (4-3)-th time point t43 to a (4-4)-th time point t44, the peripheral circuit 120 (FIG. 1) may apply the first settling voltage Vst1 to the selected word line. The temporary drive regulator IReg may provide the first settling voltage Vst1. The temporary drive regulator IReg may generate the first settling voltage Vst1 from a time point before the (4-3)-th time point t43. The temporary drive regulator IReg may immediately provide the first settling voltage Vst1 to the selected word line from the (4-3)-th time point t43 corresponding to the switching time point by generating the first settling voltage Vst1 in advance at a time point earlier than the (4-3)-th time point t43 which is the switching time.

During a (4-4)-th period p44 from a (4-4)-th time point t44 to a (4-5)-th time point t45, the peripheral circuit 120 (FIG. 1) may apply the second settling voltage Vst2 to the selected word line. The normal drive regulator NReg may provide the second settling voltage Vst2. The normal drive regulator NReg may generate the second settling voltage Vst2 from a time point before the (4-4)-th time point t44.

The second settling voltage Vst2 may be the same voltage as the first settling voltage Vst1. Since the temporary drive regulator IReg provides the first settling voltage Vst1, the normal drive regulator NReg may perform the operation performed by the temporary drive regulator IReg instead of the temporary drive regulator IReg which is literally temporarily driven.

Since the normal drive regulator NReg generates and provides the overdrive voltage Vod to the selected word line during the (4-2)-th period p42, the first settling voltage Vst1 may not be quickly provided to the selected word line in the immediately following (4-3)-th period p43. Thus, the temporary drive regulator IReg may provide the first settling voltage Vst1 to the selected word line only for the (4-3)-th period p43 until the normal drive regulator NReg provides the second settling voltage Vst2 to the selected word line. Finally, the normal drive regulator NReg stably provides the second settling voltage Vst2 to the selected word line.

For example, when an overdrive operation is performed during a read operation on a selected word line, the overdrive voltage Vod generated by the normal drive regulator NReg is provided to the selected word line, and the regulator which provides the voltage to the selected word line switches from the normal drive regulators NReg to the temporary drive regulators IReg at the (4-3)-th time point t43. Thus, the first settling voltage generated by the temporary drive regulator IReg is provided to the selected word line from the (4-3)-th point t43. The regulator which provides the voltage to the selected word line switches from the temporary drive regulator IReg to the normal drive regulator NReg at the (4-4)-th time point t44. Thus, the second settling voltage Vst2 generated by the normal drive regulator NReg is provided to the selected word line from the (4-4)-th time point t44.

A conventional memory device performs an overdrive operation on a selected word line by applying an overdrive voltage and a settling voltage generated and provided from one regulator to the selected word line. In the conventional memory device, when a strong overdrive voltage is applied to the word line to shorten an overdrive operation time, the time for the regulator generating the strong overdrive voltage to generate and provide the settling voltage to the selected word line may be increased. That is, the settling period p33′ may end at a (3-4’)-th time point t34′.

Therefore, in the conventional memory device, it was not easy to shorten the overdrive operation time of the memory device.

When the memory device according to the fourth embodiment of the present disclosure performs an overdrive operation on a selected word line, an overdrive voltage and a settling voltage are generated from different regulators and provided to the selected word line. Therefore, the overdrive voltage and the settling voltage are provided from the regulators generating different voltages, not one regulator, and are immediately applied to the selected word line, thereby easily reducing an overdrive operation time of the memory device.

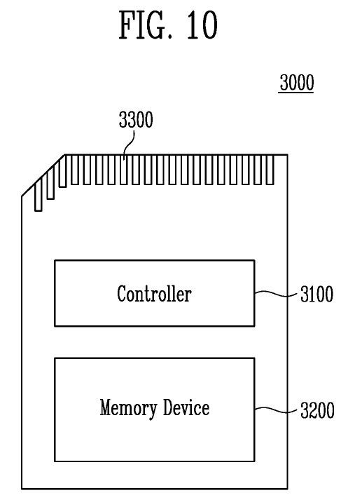

FIG. 10 is a diagram illustrating a memory card system 3000 to which a memory device according to an embodiment of the present disclosure, is applied.

Referring to FIG. 10, the memory card system 3000 may include a controller 3100, a memory device 3200, and a connector 3300.

The controller 3100 may be coupled to the memory device 3200. The controller 3100 may access the memory device 3200. For example, the controller 3100 may control a program, read, or erase operation, or a background operation of the memory device 3200. The controller 3100 may be configured to provide an interface between the memory device 3200 and a host. The controller 3100 may be configured to drive firmware for controlling the memory device 3200. For example, the controller 3100 may include components, such as a Random Access Memory (RAM), a host interface, a memory interface, and an ECC circuit.

The controller 3100 may communicate with an external device through the connector 3300. The controller 3100 may communicate with an external device (e.g., a host) based on a specific communication protocol. For example, the controller 3100 may communicate with the external device through at least one of various communication standards or interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe) protocols. In an embodiment, the connector 3300 may be defined by at least one of the above-described various communication standards or interfaces.

The memory device 3200 may include a plurality of memory cells and be configured in the same manner as the memory device 100 shown in FIG. 1.

The controller 3100 and the memory device 3200 may be integrated into a single semiconductor device to form a memory card. For example, the controller 3100 and the memory device 3200 may be integrated into a single semiconductor device to form a memory card, such as a personal computer memory card international association (PCMCIA) card, a compact flash (CF) card, a smart media card (SM, or SMC), a memory stick, a multimedia card (MMC, RS-MMC, MMCmicro, or eMMC), an SD card (SD, miniSD, microSD, or SDHC), a universal flash storage (UFS), and the like.

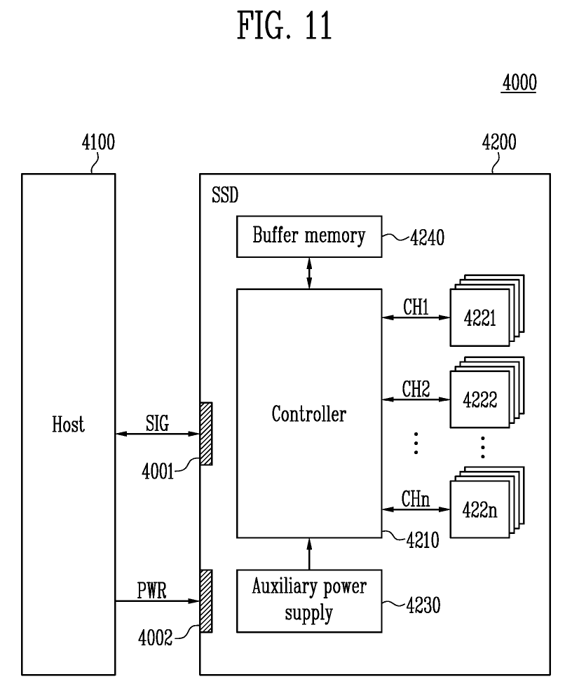

FIG. 11 is a block diagram illustrating a solid state drive (SSD) system 4000 to which a memory device according to an embodiment of the present disclosure is applied.

Referring to FIG. 11, the SSD system 4000 may include a host 4100 and an SSD 4200. The SSD 4200 may exchange signals with the host 4100 through a signal connector 4001 and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to the signals received from the host 4100. In an embodiment, the signals may be based on the interfaces of the host 4100 and the SSD 4200. For example, the signals may be defined by at least one of various communication standards or interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe) interfaces.

The plurality of memory devices 4221 to 422nmay include a plurality of memory cells which are configured to store data. Each of the plurality of memory devices 4221 to 422nmay be configured in the same manner as the memory device 100 shown in FIG. 1.

The auxiliary power supply 4230 may be coupled to the host 4100 through the power connector 4002. The auxiliary power supply 4230 may be supplied and charged with the power from the host 4100. The auxiliary power supply 4230 may supply the power of the SSD 4200 when the power is not smoothly supplied from the host 4100. In an embodiment, the auxiliary power supply 4230 may be positioned inside or outside the SSD 4200. For example, the auxiliary power supply 4230 may be disposed in a main board and supply auxiliary power to the SSD 4200.

The buffer memory 4240 may serve as a buffer memory of the SSD 4200. For example, the buffer memory 4240 may temporarily store data received from the host 4100 or data received from the plurality of memory devices 4221 to 422n, or may temporarily store metadata (e.g., mapping tables) of the memory devices 4221 to 422n. The buffer memory 4240 may include volatile memories such as DRAM, SDRAM, DDR SDRAM, and LPDDR SDRAM, or nonvolatile memories such as FRAM, ReRAM, STT-MRAM, and PRAM.

According to the embodiments of the present disclosure, performance of a memory device may be improved by reducing a stabilization time of a read operation of the memory device.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. Therefore, the embodiments disclosed above and in the accompanying drawings should be considered in a descriptive sense only and not for limiting the technological scope. The technological scope of the present disclosure is not limited by the embodiments and the accompanying drawings. Furthermore, the embodiments may be combined to form additional embodiments.

What is claimed is:

1. A memory device comprising:
a plurality of word lines coupled to a plurality of memory cells;
a peripheral circuit configured to select a first word line from among the plurality of word lines and perform a forced drive operation of sequentially applying a first voltage, a forced drive voltage, and a settling voltage to the first word line; and
a control logic circuit configured to control the peripheral circuit,
wherein the forced drive voltage and the settling voltage applied to the first word line are provided from different regulators, respectively.

2. The memory device of claim 1, wherein the forced drive voltage is one of an underdrive voltage and an overdrive voltage.

3. The memory device of claim 1, wherein the peripheral circuit comprises the different regulators including:
a normal drive regulator generating one of the settling voltage and the forced drive voltage; and
a temporary drive regulator generating the other of the settling voltage and the forced drive voltage.

4. The memory device of claim 3, wherein when the normal drive regulator generating the forced drive voltage is switched to the temporary drive regulator, the temporary drive regulator generates the settling voltage before switching.

5. The memory device of claim 3, wherein when the temporary drive regulator generating the forced drive voltage is switched to the normal drive regulator, the normal drive regulator generates the settling voltage before switching.

6. The memory device of claim 3, wherein the control logic circuit comprises a forced drive controller setting the temporary drive regulator in consideration of a voltage range of the settling voltage, a voltage range of the forced drive voltage, and voltage generation range information for each of the normal and temporary drive regulators.

7. The memory device of claim 6, wherein the forced drive controller includes a regulator information storage unit storing the voltage generation range information for each of the plurality of regulators.

8. A memory device comprising:
a plurality of word lines coupled to a plurality of memory cells;
a peripheral circuit configured to select a first word line from among the plurality of word lines and perform a forced drive operation of sequentially applying a first voltage, a forced drive voltage, a first settling voltage, and a second settling voltage to the first word line; and
a control logic circuit configured to control the peripheral circuit performing the forced drive operation,
wherein the forced drive voltage and the first settling voltage applied to the first word line are provided from different regulators, and the first settling voltage and the second settling voltage are provided from different regulators.

9. The memory device of claim 8, wherein the forced drive voltage is one of an underdrive voltage and an overdrive voltage.

10. The memory device of claim 8, wherein the peripheral circuit comprises the different regulators including:
a normal drive regulator generating the forced drive voltage and the second settling voltage; and
a temporary drive regulator generating the first settling voltage.

11. The memory device of claim 10, wherein when the normal drive regulator generating the forced drive voltage is switched to the temporary drive regulator, the temporary drive regulator generates the first settling voltage before switching.

12. The memory device of claim 10, wherein when the temporary drive regulator generating the first settling voltage is switched to the normal drive regulator, the normal drive regulator generates the second settling voltage before switching.

13. The memory device of claim 10, wherein the control logic circuit comprises a forced drive controller setting the temporary drive regulator in consideration of a voltage range of the first settling voltage and voltage generation range information for each of the normal and temporary drive regulators.

14. A method of operating a memory device, the method comprising:
selecting a word line from among a plurality of word lines; and
performing a forced drive operation on a selected word line,
wherein performing the forced drive operation comprises:
applying a forced drive voltage to the selected word line; and
applying a settling voltage to the selected word line,
wherein the forced drive voltage and the settling voltage applied to the selected word line are provided from different regulators, respectively.

15. The method of claim 14, wherein the forced drive voltage is one of an underdrive voltage and an overdrive voltage.

16. The method of claim 14, wherein:
one of the forced drive voltage and the settling voltage is provided from a normal drive regulator,
the other one of the forced drive voltage and the settling voltage is provided from a temporary drive regulator, and
the normal and temporary drive regulators are included in the different regulators.

17. The method of claim 16, wherein when the normal drive regulator generating the forced drive voltage is switched to the temporary drive regulator, the temporary drive regulator generates the settling voltage before switching.

18. The method of claim 16, wherein when the temporary drive regulator generating the forced drive voltage is switched to the normal drive regulator, the normal drive regulator generates the settling voltage before switching.

19. The method of claim 16, further comprising setting the temporary drive regulator in consideration of a voltage range of the settling voltage, a voltage range of the forced drive voltage, and voltage generation range information for each of the normal and temporary drive regulators.

20. The method of claim 19, further comprising storing the voltage generation range information for each of the plurality of regulators.

21. A memory device comprising:
a plurality of word lines coupled to a plurality of memory cells;
a plurality of regulators configured to generate a first voltage, a forced drive voltage, and a settling voltage for forced drive operation; and
a row decoder configured to sequentially apply the first voltage, the forced drive voltage, and the settling voltage generated by the plurality of regulators to a selected word line;
wherein the forced drive voltage and the settling voltage applied to the first word line are provided from different regulators, respectively.

22. The memory device of claim 21, wherein the forced drive voltage is one of an underdrive voltage and an overdrive voltage.

23. The memory device of claim 21, wherein the different regulators including:
a normal drive regulator generating one of the settling voltage and the forced drive voltage; and
a temporary drive regulator generating the other of the settling voltage and the forced drive voltage.

24. The memory device of claim 23, wherein when the normal drive regulator generating the forced drive voltage is switched to the temporary drive regulator, the temporary drive regulator generates the settling voltage before switching.

25. The memory device of claim 23, wherein when the temporary drive regulator generating the forced drive voltage is switched to the normal drive regulator, the normal drive regulator generates the settling voltage before switching.

26. The memory device of claim 23, wherein the control logic circuit comprises a forced drive controller setting the temporary drive regulator in consideration of a voltage range of the settling voltage, a voltage range of the forced drive voltage, and voltage generation range information for each of the normal and temporary drive regulators.

27. The memory device of claim 26, wherein the forced drive controller includes a regulator information storage unit storing the voltage generation range information for each of the plurality of regulators.
